(19) United States
(12) Patent Application Publication
(10) Pub. No.: US 2016/0270271 A1
(43) Pub. Date: Sep. 15, 2016

(54) COATING FOR ABSORBING ENERGY, ESPECIALLY THE ENERGY OF ELECTROMAGNETIC AND MECHANICAL WAVES, AND ITS USE

(71) Applicants: UNIWERSYTET WROCLAWSKI, Wroclaw (PL); POLITECHNIKA WROCLAWSKA, Wroclaw (PL)

(72) Inventors: Jacek Kaczmar, Wroclaw (PL); Hubert Kolodziej, Wroclaw (PL); Paulina Mayer, Wroclaw (PL); Andrzej Sowa, Wroclaw (PL); Stanislaw Strzelecki, Wroclaw (PL); Andrzej Vogt, Wroclaw (PL)

(21) Appl. No.: 15/032,936

(22) PCT Filed: Oct. 28, 2014
(86) PCT No.: PCT/IB2014/065663

§ 371 Date: Apr. 28, 2016

(30) Foreign Application Priority Data
Oct. 28, 2013 (PL) PL405813
Oct. 28, 2013 (PL) PL405814

(51) Int. Cl. H05K 9/00; B32B 5/16; B32B 27/42; B32B 15/16; B32B 27/40; B32B 27/14; H01Q 17/00; B32B 15/08

(52) U.S. Cl. CPC H05K 9/0081; H01Q 17/00; B32B 5/16; B32B 15/08; B32B 15/16; B32B 27/40; B32B 27/14; B32B 27/42; B32B 2264/105; B32B 2264/0235; B32B 2264/0257; B32B 2307/212; B32B 2307/56; B32B 2457/00; B32B 2419/00

(57) ABSTRACT

The coating for absorbing energy, especially the energy of electromagnetic and mechanical waves, is applicable in electrical and electronic devices and inside buildings. The coating has a substrate in the form of metal sheet or polymer plate, on which at least one absorber layer is applied. The absorber layer is in the form of loose or compressed powder grains, pellets, beads or gel, on which a polymer layer is placed. The coating absorbs energy.

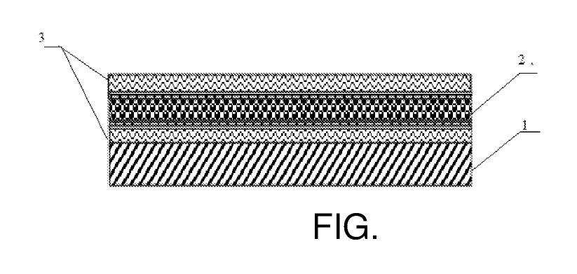

### CROSS-REFERENCE TO RELATED APPLICATIONS

See also Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

1. Field of the Invention

The object of the invention is a coating for absorbing energy, especially the energy of electromagnetic and mechanical waves, which is applicable in electrical and electronic devices, and inside buildings, and its use.

2. Description of Related Art Including Information Disclosed Under 37 CFR 1.97 and 37 CFR 1.98.

A material absorbing energy of electromagnetic waves, useful in road construction, is known from U.S. Pat. No. 7,160,049.

Materials absorbing electromagnetic waves in the range of high radio frequencies and microwaves, in which carbon fibres cut over the length, corresponding to half the length of the wave to be absorbed and immersed in a dielectric binder, are disclosed in U.S. Pat. No. 3,599,210 and U.S. Pat. No. 5,661,484.

A composite material absorbing electromagnetic waves, which can be used alone in the form of powder, in a compressed form, or as part of a multi-component composite with resins and plastics, is known from Polish patent specification 203956. The material is a nanocomposite constituting a regular arrangement of alternating layers made of kaolinite packets, having a thickness of less than 1 nm, having a low dielectric constant, and of layers of polar organic molecules, able to penetrate the kaolinite network having a very high dielectric constant, with a thickness in the range of 0.2 to 2 nm. The organic layers are composed of such organic molecules which are able to penetrate the kaolinite network, preferably of imidazole molecules. In the material according to the invention, polar molecules are linked to the kaolinite network by hydrogen bonds.

Materials absorbing electromagnetic waves, in which aluminosilicates thoroughly mixed with aluminum nitride are used, are known from French patent FR 269760.

In yet another patent document JP 1141044, a composite material, characterised in that a layer absorbing microwaves is enclosed by layers permeable to microwaves, is disclosed.

An absorbing material, formed on the basis of superabsorbent polymer plastics, the superabsorbent polymer plastics being connected to each other via a thermoplastic polymer, is known from Polish patent application P 354400. In the application, a method of manufacturing the material, which consists in that the superabsorbent polymer plastics with a moisture content of at least 0.5% by weight, relative to the total weight of the superabsorbent polymer plastics, and the thermoplastic polymer, are subjected to extrusion, wherein liquid is evaporated from the superabsorbent polymer plastics, by frothing the material, is also disclosed.

A composite material for absorbing electromagnetic waves, which consists of: a ferrimagnetic substance synergising magnetic and dielectric properties, referred to as being a non-stoichiometric complex chemical compound with a ferrimagnetic group having a spinel structure, containing ions of iron +3 and iron +2 and oxygen atoms, coordinated with carboxyl groups of saturated and/or unsaturated fatty acids, ferromagnetic material of ferrite or ferromagnetic metal type or a mixture of both, aryl or alkyl ester of an inorganic acid or a mixture of both, optionally further an admixture of elastomer and/or plasticiser, is known from another patent specification GB 2379331.

A ferrimagnetic synergising material is obtained by mixing, at an appropriate ratio, an aqueous solution of iron (III) salt and of iron (II) salt with an unsaturated fatty acid, then the mixture is heated and a strong base is added to form a precipitate. Then, the precipitate is washed and dissolved in an appropriate solvent.

The extractant forms a colloidal solution, and then acetone is added to form a solid precipitate.

A material for absorbing energy of electromagnetic wave, consisting of a resistive material dispersed in a dielectric and simultaneously connected to a conductive material in such proportions that numerically equal amounts of energy of electric and magnetic fields are dispersed, thereby wave impedance of this medium is almost entirely resistive, is known from another patent specification GB 679259. Particles of the resistive material, e.g. divided iron or a non-magnetic material, may be dispersed in a volume of the dielectric around coaxial cable in order to induce isotropic energy absorption through the material. The material may be formed into blocks or disks, or stretched along a cable guide. Optimum particle radius is of the order of half the wavelength, for measurement in the material of which the particles are made. In a line which has guides distributed, there may be additional dielectric layers having resistive and conductive particles appropriately distributed. Thickness of these layers should be lower than one radian. Electric length of the air-filled line can be increased by surrounding the guide with an absorbing medium having an appropriate thickness.

In the publication by A. A. Vogt, H. A. Kolodziej A. E. Sowa, “New Generation of Absorbing Materials”, Proc. of 15th Int. Wroclaw Symp. on EMC, Wroclaw, Jun. 27-30, 2000 ,Vol. 2, 579-582, research results of dielectric and magnetic permittivity of materials having electromagnetic wave absorption properties are described. Materials referred to as KWE and REC were the examined absorbers. One of these materials is used for coating EMC specialist cables. These materials can also be used as fillers for rigid foams.

From the publication by A. A. Vogt, H. A. Kolodziej, A. E. Sowa “An Effective Solution to the Problem of Ferrite Tile Gap Effect” Proc. of 2001 IEEE EMC International Symposium Montreal, Aug. 13-17, 2001, Vol. 1, 179-182, the use of materials is known, e.g. REC-65 can be used in non-reflecting chambers as substitutes for traditional materials with which these chambers are lined. In the publication, samples having dimensions of 100×100 mm, made of ferrite tiles in which there are empty slots, are described. Occurrence of these slots drastically reduces the effectiveness of electromagnetic wave attenuation.

From another publication, by A. A. Vogt, H. A. Kolodziej, A. E. Sowa, “Absorbing Materials for L, S, C Bands”, Proc. of 16th Int. Wroclaw Symp. on EMC, Wroclaw, Jun. 25-28, 2002, Vol. 2, 595-598, materials which may be used as absorbers in devices with antennas, in anechoic chambers in order to reduce Radar Cross Section (RCS), are known. These materials, due to the possibility of changing mechanical properties, can also be used as paints, putties, fillers and magnetic fluids having electromagnetic wave attenuation properties.

From yet another publication, by A. A. Vogt, H. A. Kolodziej, A. E. Sowa, “Single-layer Broadband Absorbers for the Range of 1-6 GHz Using New Absorbing Materials” Proc. of Int. Symp. on Electromagnetic Compatibility EMC Europe 2002, Sep. 9-13, 2002 Sorrento, Italy, Vol. 2, 683-686, materials which may be, depending on their form; rigid, hard, flexible or soft, are known. In the article, their use in cables as an insulation against electromagnetic disturbance is mentioned.

In the publication by A. A.Vogt, H. A. Kolodziej, A. E. Sowa “Hybrid absorber using new absorbing composites”, Proc. of 2005 IEEE Int. Symp. on EMC, EMC Society 2005, IEEE Operation Center, Chicago, Ill., Aug. 8-12, 2005 Vol. 2, 315318, a composite material having absorption properties (REC-1), in the form of pyramids (50 mm), also containing a ferrite layer (6 mm), is disclosed.

In yet another publication, by A. Vogt, H. A. Kolodziej, A. E. Sowa, “A new composite absorbing material which is highly effective at the lower frequencies of the VHF range, and its applications” Proc. 2006 IEEE International Symposium on Electromagnetic Compatibility : EMC 2006, Portland, Oreg. USA, 14-18 Aug. 2006/IEEE EMC Society 2, 522-525, a composite material having absorption properties in the low frequency range (VHF range) is described. The material in the form of double layer absorbers in which one layer is constituted by ferrite, and the other—by new composite materials.

### BRIEF SUMMARY OF THE INVENTION

The essence of the solution according to the invention is a coating for absorbing energy, especially the energy of electromagnetic and mechanical waves, characterised in that it has a substrate in the form of metal sheet or polymer plate, at least one absorber layer, the absorber layer being in the form of loose or compressed powder grains, pellets, beads or gel, on which the polymer layer being placed.

Preferably, the absorber layer comprises a ferrimagnetic substance FF which is a non-stoichiometric complex chemical compound with a ferrimagnetic group having a spinel structure, containing ions of ferromagnetic elements and oxygen atoms, coordinated with carboxyl groups of saturated and/or unsaturated fatty acids, a ferromagnetic material of ferrite type having a general formula of MexFe1-x[Me1-xFe1+xO4], where x is higher than or equal to 0 or lower than or equal to 1, aryl or alkyl ester of an inorganic acid or a mixture of both.

Preferably, the absorber layer comprises iron powder or powder of metallic alloys.

Preferably, the powder of metallic alloys comprises metals selected from Cr, Mo, Ni, Co, V.

Preferably, the absorber layer comprises an admixture of an elastomer selected from the group of polystyrene-polybutadiene or polypropylene-polystyrene copolymers, and thermoplastic rubbers.

Preferably, the esters are chosen from esters of inorganic acids, including phosphates, carbonates, and esters of organic acids, such as oxalates, phthalates, succinates.

Preferably, the absorber layer comprises an admixture of a plasticiser selected from the group of: diethyl oxalate, di (2-ethylhexyl) phthalate, butyl octyl phthalate, diethyl phthalate, dibutyl succinate, diisobutyl succinate, hexyl oleate, petroleum fractions, including paraffins.

Preferably, the absorber layer comprises FF of 17.5 to 32.5%, ferrites of 60 to 75%, aryl or alkyl esters of 1-3%, an elastomer of 1 to 3% and a plasticiser of 0.2 to 1.5%.

Preferably, the absorber layer comprises FF of 43.8 to 60%, ferrites of 35 to 50%, aryl or alkyl esters of 1-5% and an elastomer of 0.2 to 1.2%.

Preferably, the absorber layer comprises FF of 43.8 to 60%, ferrites of 20 to 30%, iron powder or powder of ferromagnetic metals of 15 to 30%, aryl or alkyl esters of 1 to 5% and a plasticiser of 0.2 to 1.2%.

Preferably, the substrate is a rough metal sheet, including steel, copper, aluminum or duralumin one.

Preferably, the substrate is a rigid or flexible polymer plate.

Preferably, the substrate is a spatial product.

Preferably, the absorber is a laminated polymer layer.

Preferably, between the substrate and the absorber layer, there is a polymer layer.

Preferably, the polymer layer is a polyurethane or a polyurea elastomer.

Preferably, particles of the absorber in the absorber layer (2) have a globular shape with a size of less than 2 to 3 mm.

The essence of the solution according to the invention is also the use of the coating for absorbing energy of electromagnetic waves, which has a substrate on which a polymer layer which is a polyurethane is placed, on which an absorber layer is placed, with a grain size of 2 to 3 mm, with a composition of 44% by weight of ferromagnetic substance FF which is a cluster with ions of Fe+2 and Fe+3 of spinel structure, non-stoichiometrically coordinated with carboxyl groups of oleic acid, 51% of iron-manganese-zinc ferrite, 4% of ester in the form of tributyl phosphate, and 1% of plasticiser which is a petroleum fraction with a boiling point of 250-280° C., and then the top layer is constituted by a polymer layer in the form of a polyurea elastomer, in the military industry, especially to reduce the radar cross section and to increase the shielding of objects exposed to wave interception of information and to attacks from outside with high power electromagnetic pulse.

Preferably, the substrate is a steel sheet.

In a preferred embodiment, the coating for absorbing the energy of electromagnetic waves is constituted by a mixture of the absorber layer in the amount of 70% with the polyurethane in the amount of 30%.

The method of measuring absorption level is based on the measurement of the level of signal reflected from the surface of the coating prepared on a steel substrate with respect to a steel substrate without any absorption layer applied. In the first step, measurement of the level of surrounding noise background is performed, which consists in determining the distance in the antenna area for which minimum of received signal reflected from the chamber walls and the trolley, without the measuring plate, is obtained, in order to ensure the greatest dynamics of measurement compared to the level of signal reflected from the measuring plate mounted on the trolley. As a result of this measurement, the distance between the antennas and the trolley on the crane was determined to be 2.44 m.

In the second step, reference measurement is performed, which consists in that level of the signal reflected from the steel plate (reference plate) not covered with the coating is measured.

In the third step, proper measurement is performed, i.e. measurement of the signal reflected from the steel plate with the polymer coating having electromagnetic wave absorption properties applied.

In the measurement method used, the relative difference of the levels measured in the above two steps is assumed as an absorption measure for materials attenuating electromagnetic waves. The level of absorption of the coatings prepared on the steel substrate is determined relative to the level of the signal reflected from the steel plate not covered with the coating.

A single layer polyurea coating without any absorbing material with P symbol was used as a control coating.

During the measurements, a testing signal is generated by a microwave generator and is transmitted into space by a transmitting horn antenna. The signal reflected from the surface of the coating is measured by means of a receiving horn antenna and a broadband receiver. To perform attenuation tests, signal generator SMF 100 A, two horn antennas operating in a frequency band of 1 GHz to 18 GHz and broadband receiver ESIB 26 are used.

### BRIEF DESCRIPTION OF THE SEVERAL VIEWS OF THE DRAWINGS

The object of the invention has been described in its embodiments and in the drawing.

The FIGURE is a schematic view of a coating according to the present invention.

### DETAILED DESCRIPTION OF THE INVENTION

### Example 1

A coating for absorbing energy, especially the energy of electromagnetic and mechanical waves, is equipped with a steel substrate 1 on which an absorber layer 2 is located, containing a ferromagnetic substance FF in the amount of 43.8%, with a spinel group containing pairs of ions Fe⁺³, Fe⁺², which is non-stoichiometrically coordinated with a carboxyl group of stearic acid, ferrite in the form of MnFe₂O₄ in the amount of 50%, triphenyl phosphate in the amount of 5% and a plasticiser in the form of diethyl oxalate in the amount of 1.2%, wherein the absorber layer 2 is in the form of powder grains of a size below 2 mm, which is compressed, and then on the absorber layer 2, a polymer layer 3 in the form of polyurethane is placed.

### Example 2

A coating for absorbing energy, especially the energy of electromagnetic and mechanical waves, has a substrate 1, which is constituted by a rigid polymer layer, and on which an absorber layer 2 is placed, containing a ferromagnetic substance FF in the amount of 60%, with a spinel group containing pairs of ions Fe⁺³, Fe⁺², Co⁺², which is non-stoichiometrically coordinated with a carboxyl group of oleic acid, ferrite in the form of BaFe₂O₄ in the amount of 38.8%, tributyl phosphate in the amount of 1% and a plasticiser in the form of (2-ethylhexyl) phthalate in the amount of 0.2%. The absorber layer 2 has loosely-arranged pellets of a size of 2.5 mm, and the polymer layer 3 is constituted by a polyurea elastomer.

### Example 3

A coating for absorbing energy, especially the energy of electromagnetic and mechanical waves, has a substrate 1, which is constituted by a rough copper sheet, and on which an absorber layer 2 is placed, containing a ferromagnetic substance FF in the amount of 46.5%, with a spinel group containing pairs of ions Fe⁺³, Fe⁺², Co⁺², Mn⁺², which is non-stoichiometrically coordinated with a carboxyl group of oleic acid, ferrite in the form of ZnFe₂O₄ in the amount of 50%, dibutyl carbonate in the amount of 2.5%. The absorber layer 2 comprises a plasticiser in the form of butyl octyl phthalate in the amount of 1% and has beads of a size of 3 mm, which are compressed, and the polymer layer 3 is constituted by a polyurethane.

### Example 4

A coating for absorbing energy, especially the energy of electromagnetic and mechanical waves, has a substrate 1, which is constituted by a rough metal sheet, and on which an absorber layer 2 is placed, containing a ferromagnetic substance FF, with a spinel group containing pairs of ions Fe⁺³, Fe⁺², Co⁺², Mn⁺², Zn⁺², which is non-stoichiometrically coordinated with a carboxyl group of oleic acid in the amount of 25%, ferrite in the form of NiFe₂O₄ in the amount of 70.3%, diethyl phthalate in the amount of 2%. The absorber layer 2 comprises a plasticiser in the form of di (2-ethylhexyl) phthalate in the amount of 0.7% and an elastomer which is a polystyrene-polybutadiene copolymer in the amount of 2%, has beads of a size of 3 mm, which are arranged loosely, and the polymer layer 3 is constituted by a polyurea elastomer.

### Example 5

A coating for absorbing energy, especially the energy of electromagnetic and mechanical waves, has a substrate 1, which is constituted by a spatial product, and on which an absorber layer 2 is placed, containing a ferromagnetic substance FF, with a spinel group containing pairs of ions Fe⁺³, Fe⁺², Co⁺², Mn⁺², Zn⁺², which is coordinated with a carboxyl group of oleic acid in the amount of 32.5%, ferrite in the form of CoFe₂O₄ in the amount of 60%, mixture of esters of triethyl phosphate with triphenyl phosphate in the amount of 3%, the abosrber layer comprises also an admixture of elastomers in the form of polypropylene-polystyrene copolymer in the amount of 3% and a plasticiser in the form of dibutyl succinate in the amount of 1.5%. The absorber layer 2 is in the form of gel, and the polymer layer 3 is constituted by a polyurea elastomer.

### Example 6

A coating for absorbing energy, especially the energy of electromagnetic and mechanical waves, has a substrate 1, which is constituted by a spatial product, and on which an absorber layer 2 is placed, containing a ferromagnetic substance FF, with a spinel group containing pairs of ions Fe⁺³, Fe⁺², Co⁺², Mn⁺², Zn⁺², which is coordinated with a carboxyl group of oleic acid in the amount of 22.8%, ferrite in the form of CoFe₂O₄ in the amount of 75%, mixture of esters of triethyl phosphate with triphenyl phosphate in the amount of 1%, the abosrber layer comprises also an admixture of elastomers in the form of thermoplastic rubber in the amount of 1% and a plasticiser in the form of dibutyl succinate in the amount of 0.2%. The absorber layer 2 is in the form of gel, and the polymer layer 3 is constituted by a polyurea elastomer.

### Example 7

A coating for absorbing energy, especially the energy of electromagnetic and mechanical waves, has a substrate 1, which is constituted by a flexible polymer plate, and on which an absorber layer 2 is placed, containing a ferromagnetic substance FF in the amount of 22.8%, with a spinel group containing pairs of ions Fe⁺³, Fe⁺², Co⁺², which is non-stoichiometrically coordinated with a carboxyl group of stearic acid, ferrite in the form of LaFe₂O₄ in the amount of 75%, triethyl phosphate in the amount of 1% and a plasticiser in the form of diethyl phthalate in the amount of 0.2%. The absorber layer 2 has pellets of a size of 2.5 mm, and the polymer layer 3 is constituted by a polyurea elastomer.

### Example 8

A coating for absorbing energy, especially the energy of electromagnetic and mechanical waves, has a substrate 1, which is constituted by a rough aluminum sheet, and on which an absorber layer 2 is placed, containing a ferromagnetic substance FF in the amount of 43.8%, with a spinel group containing pairs of ions Fe⁺³, Fe⁺², Co⁺², which is non-stoichiometrically coordinated with a carboxyl group of stearic acid, ferrite in the form of BaFe₂O₄ in the amount of 30%, with an admixture of iron powders in the amount of 20%, dibutyl succinate in the amount of 5% and a plasticiser in the form of diisobutyl succinate in the amount of 1.2%. The absorber layer 2 has pellets of a size of 2.5 mm, and the polymer layer 3 is constituted by a polyurea elastomer.

### Example 9

A coating for absorbing energy, especially the energy of electromagnetic and mechanical waves, has a substrate 1, which is constituted by a rough duralumin sheet, and on which an absorber layer 2 is placed, containing a ferromagnetic substance FF in the amount of 48.8%, with a spinel group containing pairs of ions Fe⁺³, Fe⁺², Co⁺², which is non-stoichiometrically coordinated with a carboxyl group of stearic acid, ferrite in the form of BaFe₂O₄ in the amount of 20%, with an admixture of chromium powders in the amount of 30%, hexyl oleate in the amount of 1% and a plasticiser in the form of dibutyl succinate in the amount of 0.2%. The absorber layer 2 is in the form of gel, and the polymer layer 3 is constituted by a polyurethane elastomer.

### Example 10

A coating for absorbing energy, especially the energy of electromagnetic and mechanical waves, has a substrate 1, which is constituted by a rigid polymer plate, and on which an absorber layer 2 is placed, containing a ferromagnetic substance FF in the amount of 60%, with a spinel group containing pairs of ions Fe⁺³, Fe⁺², which is non-stoichiometrically coordinated with a carboxyl group of stearic acid, ferrite in the form of ZnFe₂O₄ in the amount of 21.3%, with an admixture of molybdenum powders in the amount of 15%, a mixture of triphenyl phosphate with diisobutyl succinate in the amount of 3% and a plasticiser in the form of hexyl oleate in the amount of 0.7%. The absorber layer 2 is in the form of gel, and the polymer layer 3 is constituted by a polyurethane elastomer.

### Example 11

A coating for absorbing energy, especially the energy of electromagnetic and mechanical waves, as in Example 8, wherein nickel is used as the admixture of powders, petroleum fraction is used as the plasticiser.

### Example 12

A coating for absorbing energy, especially the energy of electromagnetic and mechanical waves, as in Example 9, wherein cobalt is used as the admixture of powders, diisobutyl succinate is used as the plasticiser.

### Example 13

A coating for absorbing energy, especially the energy of electromagnetic and mechanical waves, as in Example 1, wherein the absorber layer 2 is a laminated polymer layer 3.

### Example 14

A coating for absorbing energy, especially the energy of electromagnetic and mechanical waves, as in Example 1, wherein between the substrate 1 and the absorber layer 2, there is the polymer layer 3, and then the last layer is constituted by the polymer layer 3.

### Example 15

A coating for absorbing energy, especially the energy of electromagnetic and mechanical waves, as in Example 1, wherein on the substrate 1, there is the absorber layer 2 on which there is the polymer layer 3, and then on the polymer layer 3, there is the absorber layer 2 placed once again, on which the polymer layer 3 is then placed.

### Example 16

The level of absorption measurement is determined with a coating for absorbing the energy of electromagnetic waves, which is made of a substrate in the form of a steel sheet on which a polymer layer is placed, which is a polyurethane, and then, on it, there is an absorber layer having grains of a size of 2 to 3 mm, having a composition of 44% by weight of a ferromagnetic substance FF which is a cluster with ions Fe⁺² and Fe⁺³ of spinel structure, non-stoichiometrically coordinated with carboxyl groups of oleic acid, 51% of ferrite in the form of iron-manganese-zinc ferrite, 4% of ester in the form of tributyl phosphate, 1% of plasticiser which is a petroleum fraction with a boiling point of 250-280° C. (U3P coating), and then the top layer is constituted by a polymer layer in the form of a polyurea elastomer.

In Table 1, levels of received signals for U3P coating are compiled. A single layer polyurea coating without any absorbing material with P symbol was used as a control coating.

TABLE 1

| | Level of noise | | | |
|---|---|---|---|---|
| | background in | Sample 0 | | |
| | the chamber | steel plate | U3P | P |
| f [GHz] | [dB] | [dB] | [dB] | [dB] |
| 1.00 | −40.60 | −37.30 | −41.60 | −37.31 |
| 1.50 | −46.70 | −30.70 | −34.26 | −30.71 |
| 2.00 | −36.80 | −26.20 | −28.30 | −26.43 |
| 2.50 | −41.20 | −31.33 | −39.16 | −31.34 |
| 3.00 | −37.60 | −25.90 | −33.20 | −26.51 |
| 3.50 | −52.82 | −29.01 | −39.60 | −29.94 |
| 4.00 | −49.40 | −31.90 | −43.02 | −33.00 |
| 4.50 | −42.70 | −35.26 | −49.30 | −35.78 |
| 5.00 | −48.20 | −35.08 | −51.20 | −35.55 |
| 5.50 | −54.72 | −34.86 | −49.70 | −35.64 |
| 6.00 | −60.10 | −34.90 | −45.80 | −35.33 |
| 6.50 | −52.14 | −36.90 | −47.20 | −38.09 |
| 7.00 | −48.30 | −38.40 | −50.60 | −39.55 |
| 7.50 | −49.60 | −38.70 | −51.50 | −40.02 |
| 8.00 | −49.60 | −40.43 | −52.03 | −41.25 |
| 8.50 | −49.30 | −41.30 | −53.02 | −42.23 |
| 9.00 | −48.70 | −39.40 | −47.20 | −41.56 |
| 9.50 | −55.60 | −44.20 | −51.50 | −46.55 |
| 10.00 | −62.40 | −48.70 | −58.20 | −50.91 |

In Table 2, absorption levels of signals for U3P coating and dynamic range of measurements are compiled.

TABLE 2

| | Level of noise | | | |
|---|---|---|---|---|
| | background in | Sample 0 | | |
| | the chamber | steel plate | U3P | P |
| f [GHz] | [dB] | [dB] | [dB] | [dB] |
| 1.00 | −40.60 | −37.30 | −41.60 | −37.31 |
| 1.50 | −46.70 | −30.70 | −34.26 | −30.71 |
| 2.00 | −36.80 | −26.20 | −28.30 | −26.43 |
| 2.50 | −41.20 | −31.33 | −39.16 | −31.34 |
| 3.00 | −37.60 | −25.90 | −33.20 | −26.51 |
| 3.50 | −52.82 | −29.01 | −39.60 | −29.94 |
| 4.00 | −49.40 | −31.90 | −43.02 | −33.00 |
| 4.50 | −42.70 | −35.26 | −49.30 | −35.78 |
| 5.00 | −48.20 | −35.08 | −51.20 | −35.55 |
| 5.50 | −54.72 | −34.86 | −49.70 | −35.64 |
| 6.00 | −60.10 | −34.90 | −45.80 | −35.33 |
| 6.50 | −52.14 | −36.90 | −47.20 | −38.09 |
| 7.00 | −48.30 | −38.40 | −50.60 | −39.55 |
| 7.50 | −49.60 | −38.70 | −51.50 | −40.02 |
| 8.00 | −49.60 | −40.43 | −52.03 | −41.25 |
| 8.50 | −49.30 | −41.30 | −53.02 | −42.23 |
| 9.00 | −48.70 | −39.40 | −47.20 | −41.56 |
| 9.50 | −55.60 | −44.20 | −51.50 | −46.55 |
| 10.00 | −62.40 | −48.70 | −58.20 | −50.91 |

### Example 17

The level of absorption measurement is determined with a coating for absorbing the energy of electromagnetic waves, which is made of a substrate in the form of a steel sheet on which an absorber layer in the amount of 70% is placed, having grains of a size of 3 mm, having a composition of 44% by weight of a ferromagnetic substance FF which is a cluster with ions Fe⁺² and Fe⁺³ of spinel structure, non-stoichiometrically coordinated with carboxyl groups of oleic acid, 51% of ferrite in the form of iron-manganese-zinc ferrite, 4% of ester in the form of tributyl phosphate, 1% of plasticiser which is a petroleum fraction with a boiling point of 250-280° C. (M3 coating).

In Table 3, levels of received signals for M3 coating are compiled. A single layer polyurea coating without any absorbing material with P symbol was used as a control coating.

TABLE 3

| | Level of noise | | | |
|---|---|---|---|---|
| | background | Sample 0 | | |
| | in the | steel plate | M3 | P |
| f [GHz] | chamber [dB] | [dB] | [dB] | [dB] |
| 1.00 | −40.60 | −37.30 | −40.80 | −37.31 |
| 1.50 | −46.70 | −30.70 | −34.32 | −30.71 |
| 2.00 | −36.80 | −26.20 | −28.70 | −26.43 |
| 2.50 | −41.20 | −31.33 | −38.95 | −31.34 |
| 3.00 | −37.60 | −25.90 | −35.47 | −26.51 |
| 3.50 | −52.82 | −29.01 | −43.62 | −29.94 |
| 4.00 | −49.40 | −31.90 | −45.70 | −33.00 |
| 4.50 | −42.70 | −35.26 | −44.80 | −35.78 |
| 5.00 | −48.20 | −35.08 | −46.70 | −35.55 |
| 5.50 | −54.72 | −34.86 | −45.11 | −35.64 |
| 6.00 | −60.10 | −34.90 | −42.10 | −35.33 |
| 6.50 | −52.14 | −36.90 | −44.03 | −38.09 |
| 7.00 | −48.30 | −38.40 | −47.02 | −39.55 |
| 7.50 | −49.60 | −38.70 | −47.33 | −40.02 |
| 8.00 | −49.60 | −40.43 | −48.30 | −41.25 |
| 8.50 | −49.30 | −41.30 | −49.10 | −42.23 |
| 9.00 | −48.70 | −39.40 | −44.60 | −41.56 |
| 9.50 | −55.60 | −44.20 | −49.23 | −46.55 |
| 10.00 | −62.40 | −48.70 | −55.43 | −50.91 |

In Table 4, absorption levels of signals for M3 coating and measurement dynamics are compiled.

TABLE 4

| | Dynamic range | | |
|---|---|---|---|
| | of | | |
| | measurement | | |
| f [GHz] | [dB] | M3 [dB] | P [dB] |
| 1.00 | −3.30 | −3.50 | −0.01 |
| 1.50 | −16.00 | −3.62 | −0.01 |
| 2.00 | −10.60 | −2.50 | −0.23 |
| 2.50 | −9.87 | −7.62 | −0.01 |
| 3.00 | −11.70 | −9.57 | −0.61 |
| 3.50 | −23.81 | −14.61 | −0.93 |
| 4.00 | −17.50 | −13.80 | −1.10 |
| 4.50 | −7.44 | −9.54 | −0.52 |
| 5.00 | −13.12 | −11.62 | −0.47 |
| 5.50 | −19.86 | −10.25 | −0.78 |
| 6.00 | −25.20 | −7.20 | −0.43 |
| 6.50 | −15.24 | −7.13 | −1.19 |
| 7.00 | −9.90 | −8.62 | −1.15 |
| 7.50 | −10.90 | −8.63 | −1.32 |
| 8.00 | −9.17 | −7.87 | −0.82 |
| 8.50 | −8.00 | −7.80 | −0.93 |
| 9.00 | −9.30 | −5.20 | −2.16 |
| 9.50 | −11.40 | −5.03 | −2.35 |
| 10.00 | −13.70 | −6.73 | −2.21 |

In turn, in the graph below, results of absorption (attenuation) level of tested coatings in Example 1 and 2 as a function of frequency are shown.

By analysing the measurement data, it can be concluded that the best results of absorption were obtained for layered coating U3P applied to a steel substrate. In turn, coatings obtained by mixing the polyurethane with grains of the absorber REC are characterised by worse attenuation, which is caused by dielectric dilution of the polymer.

In the case of layered coating U3P, the absorber is constituted by a uniform compact layer in which there is contact between magnetic domains over the entire surface of the absorber. Suspension of grains in the polymer leads to separation of grains (M3 coating), and thereby the contact between the domains breaks.

Based on the measurements performed, Radar Cross Section (RCS) which is a measure of signal level is calculated by known methods. Value σᵣₐₘ and indirect parameters for U3P coating and M3 coating having dimensions of 300×300 mm and a measuring distance of R=2.44 m for signal frequency of 1000 to 5000 MHz are shown in Table 5.

TABLE 5

| | Signal frequency f [MHz] | | | | | | | | |
|---|---|---|---|---|---|---|---|---|---|
| | 1000 | 1500 | 2000 | 2500 | 3000 | 3500 | 4000 | 4500 | 5000 |
| Radar cross section σ of a | 1.13 | 2.54 | 4.52 | 7.06 | 10.17 | 13.84 | 18.08 | 22.89 | 28.26 |
| perfectly reflecting | | | | | | | | | |
| rectangular surface [m²] | | | | | | | | | |
| Radar cross section 10log(σ) | 0.53 | 4.05 | 6.55 | 8.49 | 10.07 | 11.41 | 12.57 | 13.59 | 14.51 |
| of a perfectly reflecting | | | | | | | | | |
| rectangular surface [dB] | | | | | | | | | |
| Ratio of reflected power to | −37.30 | −30.70 | −26.20 | −31.33 | −25.90 | −29.01 | −31.90 | −35.26 | −35.08 |
| incident power | | | | | | | | | |
| 10log(P_{RX}/P_{TX}) for reference | | | | | | | | | |
| steel plate [dB] | | | | | | | | | |
| Proportionality factor | −37.83 | −34.75 | −32.75 | −39.82 | −35.97 | −40.42 | −44.47 | −48.85 | −49.59 |
| 10log(K) | | | | | | | | | |
| Ratio of reflected power to | −41.60 | −34.26 | −28.30 | −39.16 | −33.20 | −39.60 | −39.60 | −49.30 | −51.20 |
| incident power | | | | | | | | | |
| 10log(P_{RX}/P_{TX}) for steel | | | | | | | | | |
| plate covered with U3P | | | | | | | | | |
| coating [dB] | | | | | | | | | |
| Radar cross section σ_{RAM} of | 0.41 | 1.12 | 2.78 | 1.16 | 1.89 | 1.21 | 3.07 | 0.90 | 0.69 |
| steel plate covered with | | | | | | | | | |
| U3P coating [m²] | | | | | | | | | |
| Ratio of reflected power to | −40.80 | −34.32 | −28.70 | −38.95 | −35.47 | −43.62 | −45.70 | −44.80 | −46.70 |
| incident power | | | | | | | | | |
| 10log(P_{RX}/P_{TX}) for steel | | | | | | | | | |
| plate covered with M3 | | | | | | | | | |
| coating [dB] | | | | | | | | | |
| Radar cross section σ_{RAM} of | 0.50 | 1.10 | 2.54 | 1.22 | 1.12 | 0.48 | 0.75 | 2.54 | 1.95 |
| steel plate covered with M3 | | | | | | | | | |
| coating [m²] | | | | | | | | | |

Value σᵣₐₘ and indirect parameters for U3P coating and M3 coating having dimensions of 300×300 mm and a measuring distance of R=2.44 m for signal frequency of 5500 to 10000 MHz are shown in Table 6.

TABLE 6

| | Signal frequency f [MHz] | | | | | | | | | |
|---|---|---|---|---|---|---|---|---|---|---|
| | 5500 | 6000 | 6500 | 7000 | 7500 | 8000 | 8500 | 9000 | 9500 | 10000 |
| Radar cross section σ | 34.19 | 40.69 | 47.76 | 55.39 | 63.58 | 72.34 | 81.67 | 91.56 | 102.02 | 113.04 |
| of a perfectly reflecting | | | | | | | | | | |
| rectangular surface | | | | | | | | | | |
| [m²] | | | | | | | | | | |
| Radar cross section | 15.34 | 16.09 | 16.79 | 17.43 | 18.03 | 18.60 | 19.12 | 19.62 | 20.09 | 20.53 |
| 10log(σ) of a perfectly | | | | | | | | | | |
| reflecting rectangular | | | | | | | | | | |
| surface [dB] | | | | | | | | | | |
| Ratio of reflected | −34.86 | −34.90 | −36.90 | −38.40 | −38.70 | −40.43 | −41.30 | −39.40 | −44.20 | −48.70 |
| power to incident | | | | | | | | | | |
| power 10log(P_{RX}/P_{TX}) | | | | | | | | | | |
| for reference metal | | | | | | | | | | |
| plate | | | | | | | | | | |
| Proportionality factor | −50.19 | −50.99 | −53.69 | −55.83 | −56.73 | −59.02 | −60.42 | −59.02 | −64.29 | −69.23 |
| 10log(K) | | | | | | | | | | |
| Ratio of reflected | −49.70 | −45.80 | −47.20 | −50.60 | −51.50 | −52.03 | −53.02 | −47.20 | −51.50 | −58.20 |
| power to incident | | | | | | | | | | |
| power 10log(P_{RX}/P_{TX}) | | | | | | | | | | |
| for steel plate covered | | | | | | | | | | |
| with U3P coating [dB] | | | | | | | | | | |
| Radar cross section | 1.12 | 3.31 | 4.46 | 3.34 | 3.34 | 5.00 | 5.49 | 15.19 | 18.99 | 12.68 |
| σ_{RAM} of steel plate | | | | | | | | | | |
| covered with U3P | | | | | | | | | | |
| coating [m²] | | | | | | | | | | |
| Ratio of reflected | −45.11 | −42.10 | −44.03 | −47.02 | −47.33 | −48.30 | −49.10 | −44.60 | −49.23 | −55.43 |
| power to incident | | | | | | | | | | |
| power 10log(P_{RX}/P_{TX}) | | | | | | | | | | |
| for steel plate covered | | | | | | | | | | |
| with M3 coating [dB] | | | | | | | | | | |
| Radar cross section | 3.23 | 7.75 | 9.25 | 7.61 | 8.72 | 11.81 | 13.55 | 27.65 | 32.04 | 24.00 |
| σ_{RAM} of steel plate | | | | | | | | | | |
| covered with M3 | | | | | | | | | | |
| coating [m2] | | | | | | | | | | |

In Graph 2, radar cross section as a function of frequency for individual coatings is shown.

The advantage of the coating for absorbing energy, especially the energy of electromagnetic and mechanical waves, according to the invention, is that it has high mechanical strength, impact resistance, abrasion resistance and high resistance to weather conditions and to chemical agents.

1. A coating for absorbing energy, comprising:
a substrate comprised of one of a group consisting of a metal sheet and a polymer plate;
at least one absorber layer comprised of loose or compressed powder grains, pellets, beads or gel; and
a polymer layer is placed over the absorber layer.

2. The coating according to claim 1, wherein the absorber layer comprises a ferrimagnetic substance FF which is a non-stoichiometric complex chemical compound with a ferrimagnetic group having a spinel structure, containing ions of ferromagnetic elements and oxygen atoms, coordinated with carboxyl groups of saturated and/or unsaturated fatty acids, a ferromagnetic material of ferrite type having a general formula of MexFe1-x[Me1-xFe1+xO4], where x is higher than or equal to 0 or lower than or equal to 1, aryl or alkyl ester of an inorganic acid or a mixture of both.

3. The coating according to claim 1, wherein the absorber layer comprises iron powder or powder of metallic alloys.

4. The coating according to claim 3, wherein the powder of metallic alloys comprises metals selected from Cr, Mo, Ni, Co, and V.

5. The coating according to claim 1, wherein the absorber layer comprises an admixture of elastomer selected from the group of polystyrene-polybutadiene, polypropylene-polystyrene copolymers, and thermoplastic rubbers.

6. The coating according to claim 1, further comprising: esters of inorganic acids, including phosphates, carbonates, and esters of organic acids, such as oxalates, phthalates, succinates.

7. The coating according to claim 1, wherein the absorber layer comprises an admixture of a plasticiser selected from the group of: diethyl oxalate, di (2-ethylhexyl) phthalate, butyl octyl phthalate, diethyl phthalate, dibutyl succinate, diisobutyl succinate, hexyl oleate, petroleum fraction, and paraffins.

8. The coating according to claim 1, wherein the absorber layer comprises FF of 17.5 to 32.5%, ferrites of 60 to 75%, aryl or alkyl esters of 1-3%, an elastomer of 1 to 3% and a plasticiser of 0.2 to 1.5%.

9. The coating according to claim 1, wherein the absorber layer comprises FF of 43.8 to 60%, ferrites of 35 to 50%, aryl or alkyl esters of 1-5%, and a plasticiser of 0.2 to 1.2%.

10. The coating according to claim 1, wherein the absorber layer comprises FF of 43.8 to 60%, ferrites of 20 to 30%, iron powder or powder of ferromagnetic metals of 15 to 30%, aryl or alkyl esters of 1 to 5% and a plasticiser of 0.2 to 1.2%.

11. The coating according to claim 1, wherein the substrate is a rough metal sheet, including steel, copper, aluminum or duralumin one.

12. (canceled)

13. The coating according to claim 1, wherein the substrate is comprised of a spatial product.

14. The coating according to claim 1, wherein the absorber layer is comprised of a laminated polymer layer (3).

15. The coating according to claim 1, further comprising: another polymer layer between the substrate and the absorber layer.

16. The coating according to claim 1, wherein the polymer layer is comprised of a polyurethane or a polyurea elastomer.

17. The coating according to claim 1, wherein the absorber layer has electromagnetic wave absorption properties in the range of 100 kHz to 60 GHz.

18. The coating according to claim 1, wherein the absorber layer is comprised of absorber particles having a globular shape with a size of less than 2 to 3 mm.

19. A method for absorbing energy of electromagnetic waves, the method comprising the steps of:
applying a coating comprised of a substrate, a polymer layer being a polyurethane being placed on the substrate, and an absorber layer placed on the polymer layer, the absorber layer having a grain size of 2 to 3 mm, with a composition of 44% by weight of ferromagnetic substance FF, being a cluster with ions of Fe+2 and Fe+3 of spinel structure, non-stoichiometrically coordinated with carboxyl groups of oleic acid, 51% of iron-manganese-zinc ferrite, 4% of ester in being comprised of tributyl phosphate, and 1% of plasticiser being a petroleum fraction with a boiling point of 250-280° C., and
constituting a top layer by a polymer layer comprised of a polyurea elastomer.

20. The method for absorbing, according to claim 19, wherein the substrate is comprised of a steel sheet.

21. The method for absorbing, according to claim 19, wherein the absorber layer is in the amount of 70% with a grain size of 2 to 3 mm, with a composition of 44% by weight of ferromagnetic substance FF which is a cluster with ions of Fe+2 and Fe+3 of spinel structure, non-stoichiometrically coordinated with carboxyl groups of oleic acid, 51% of iron-manganese-zinc ferrite, 4% of ester in the form of tributyl phosphate, and 1% of plasticiser which is a petroleum fraction with a boiling point of 250-280° C., with polyurethane in the amount of 30%.
